(19) United States
(12) Patent Application Publication
(10) Pub. No.: US 2023/0286403 A1
(43) Pub. Date: Sep. 14, 2023

(54) SYSTEMS FOR DETECTING DC ARC FAULT IN BATTERY SYSTEM CHARGERS FOR ELECTRIC VEHICLES

(71) Applicant: GM GLOBAL TECHNOLOGY OPERATIONS LLC, Detroit, MI (US)

(72) Inventors: Suresh GOPALAKRISHNAN, Troy, MI (US); Chandra S. Namuduri, Troy, MI (US); Muhammad Hussain Alvi, Troy, MI (US)

(21) Appl. No.: 17/694,196

(22) Filed: Mar. 14, 2022

(51) Int. Cl. B60L 53/62; H02J 7/00; B60L 53/16; G01R 31/52; G01R 15/20; G01R 19/165

(52) U.S. Cl. CPC B60L 53/62; B60L 53/16; G01R 15/20; G01R 19/16566; G01R 31/52; H02J 7/0029; H02J 7/0042; H02J 7/0047

(57) ABSTRACT

A charging system for an electric vehicle comprises a charger connector configured to connect to a charge port on the electric vehicle and includes a housing, a first conductor passing through the housing, a second conductor passing through the housing, and a current sensor configured to sense current flowing through at least one of the first conductor and the second conductor to a battery system of the electric vehicle. A charger-side controller includes an arc fault detection module configured to selectively identify a DC arc fault in response to measured current sensed by the current sensor and to stop charging the electric vehicle in response to detecting the DC arc fault.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to charging systems for electric vehicles, and more particularly to systems for detecting DC arc faults in charging systems for electric vehicles.

Electric vehicles such as plug-in hybrid vehicles, battery electric vehicles and fuel cell vehicles include a battery system including one or more battery cells, modules and/or packs. The battery system needs to be charged using a charging system. Some charging systems for battery systems require 4-10 hours to recharge the electric vehicle. Fast charging systems are being developed to charge the electric vehicles at higher voltage levels such as 400 V or 800 V to reduce the amount of time required to charge the battery systems of the electric vehicles.

DC Fast Charging (DCFC) systems use a standard set of connectors that are adapted by different original equipment manufacturers (OEMs) in various countries. The connectors are designed to meet the electrical, mechanical and environmental requirements to ensure safe operation during charging at high voltage levels.

### SUMMARY

A charging system for an electric vehicle comprises a charger connector configured to connect to a charge port on the electric vehicle and includes a housing, a first conductor passing through the housing, a second conductor passing through the housing, and a current sensor configured to sense current flowing through at least one of the first conductor and the second conductor to a battery system of the electric vehicle. A charger-side controller includes an arc fault detection module configured to selectively identify a DC arc fault in response to measured current sensed by the current sensor and to stop charging the electric vehicle in response to detecting the DC arc fault.

In other features, the current sensor has a bandwidth greater than 100 KHz. The current sensor comprises a point field detector (PFD). The current sensor is selected from a group consisting an anisotropic magneto-resistive (AMR) sensor, a giant magneto-resistive (GMR) sensor, a tunnel magneto-resistive (TMR) sensor, and a Hall effect sensor. When stopping charging, the charger-side controller is configured to decrease current output to the electric vehicle to zero and send a message to a vehicle-side controller to cause the vehicle-side controller to open a first contactor and a second contactor connecting the first conductor and the second conductor to the battery system after the measured current is less than a predetermined current threshold.

In other features, the current sensor is arranged in the housing. The current sensor is arranged between the first conductor and the second conductor in the housing. An insulation layer surrounds the first conductor and the second conductor. The current sensor is arranged around the insulation layer. A voltage sensor is configured to sense voltage across the first conductor and the second conductor.

In other features, the charger-side controller receives a second measured current and a second measured voltage from a vehicle-side controller. The arc fault detection module is configured detect the DC arc fault by comparing the measured current and the measured voltage to the second measured current and the second measured voltage, respectively.

A charging system for an electric vehicle includes a charge port on the electric vehicle configured to connect to a charger connector, a first conductor configured to connect power from the charge port to a first terminal of a battery system, and a second conductor configured to connect power from the charge port to a second terminal of the battery system. A current sensor is configured to sense current flowing through at least one of the first conductor and the second conductor to the battery system. A vehicle-side controller includes an arc fault detection module configured to selectively identify a DC arc fault in response to measured current output by the current sensor and to cause charging to stop in response to detecting the DC arc fault.

In other features, the current sensor has a bandwidth greater than 100 KHz. The current sensor comprises a point field detector (PFD). The current sensor is selected from a group consisting an anisotropic magneto-resistive (AMR) sensor, a giant magneto-resistive (GMR) sensor, a tunnel magneto-resistive (TMR) sensor, and a Hall effect sensor. A first contactor connects the first conductor to the first terminal of the battery system. A second contactor connects the second conductor to the second terminal of the battery system. When causing the charging to stop, the vehicle-side controller is configured to send a message to a charger-side controller to decrease current output to the electric vehicle to zero and open the first contactor and the second contactor after the measured current is less than a predetermined current threshold.

In other features, a voltage sensor configured to sense voltage across the first conductor and the second conductor. The vehicle-side controller receives a second measured current and a second measured voltage from a vehicle-side controller. The arc fault detection module is configured detect the DC arc fault by comparing the measured current and the measured voltage to the second measured current and the second measured voltage, respectively.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a charging system for charging an electric vehicle;

FIGS. 2A and 2B are graphs illustrating current and voltage as a function of time and including DC arc flashes due to serial or parallel faults, respectively;

FIG. 3 is a perspective view of an example of a charging system according to the present disclosure;

FIGS. 4-7 are functional block diagrams of examples of charging systems for charging an electric vehicle according to the present disclosure;

FIGS. 8 and 9 illustrate examples of locations for mounting the current sensor on the charging plug or charging port; and

FIGS. 10 and 11 are flowcharts illustrating examples of method for operating the charging system according to the present disclosure.

In the drawings, reference numbers may be reused to identify similar and/or identical elements.

### DETAILED DESCRIPTION

Charging stations include a plurality of charging systems that are typically located outdoors and are therefore not in temperature and humidity-controlled environments. The charging stations supply DC power from a DC source (e.g. utility power). In coastal areas, the charger connectors are also vulnerable to build up moisture and salt, which may compromise a creepage distance and cause DC arc faults to occur. Since DC arc faults do not cause over-current or over-voltage conditions, DC arc faults go undetected by the standard protection devices used in the charging systems.

Charging systems and methods according to the present disclosure monitor current flowing from a charging system to an electric vehicle via a charge connector. The charging systems detect DC arc faults during charging of the electric vehicle. Examples of DC arc faults include series or parallel DC arc faults. Both types of DC arc faults have unique current signatures that can be detected by processing current and/or voltage waveforms measured using the current or voltage sensors. In some examples, the current sensors are high bandwidth sensors. As used herein, high bandwidth refers to bandwidths greater than 100 kHz.

In some examples, a current sensor is arranged in the charger connector on the charger side. An arc fault detection module of a charger-side controller detects the DC arc faults based on the current sensed by the current sensor. When a DC arc fault is detected, the charger-side controller reduces the charging current to zero within a predetermined period. The charger-side controller sends a message to vehicle-side controller to open the battery contactor after the charging current falls below a predetermined threshold.

In some examples, the current sensor is located on the vehicle side. When the DC arc fault is detected, the vehicle-side controller sends a request to the charger-side controller reduce the charging current to zero within a predetermined period. The vehicle-side controller opens the battery contactors after the charging current falls below a predetermined current threshold.

In some examples, both current and voltage sensors monitor current and voltage levels on one or both of the charger side and the vehicle side. The charger-side controller and/or the vehicle-side controller compare the two sets of voltages and currents. Under normal operating conditions, the two voltages and currents will be within predetermined ranges of one another. Any deviation beyond the predetermined ranges indicates a potential fault and charging is stopped.

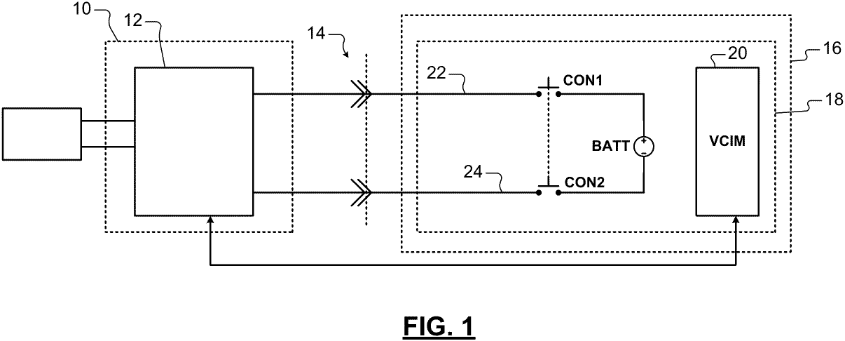

Referring now to FIG. 1, a charging system 10 for charging an electric vehicle 16 is shown. The charging system 10 includes a charger-side controller 12 to control the supply of charging current from a DC source to the electric vehicle and a plug 14 to connect to a port on an electric vehicle 16. The electric vehicle 16 includes a battery system 18 including contactors CON1 and CON2 connecting insulated conductors 22 and 24 to terminals of a battery BATT. The battery BATT includes one or more battery cells, battery modules, and/or battery packs connected in series, parallel, and/or combinations thereof.

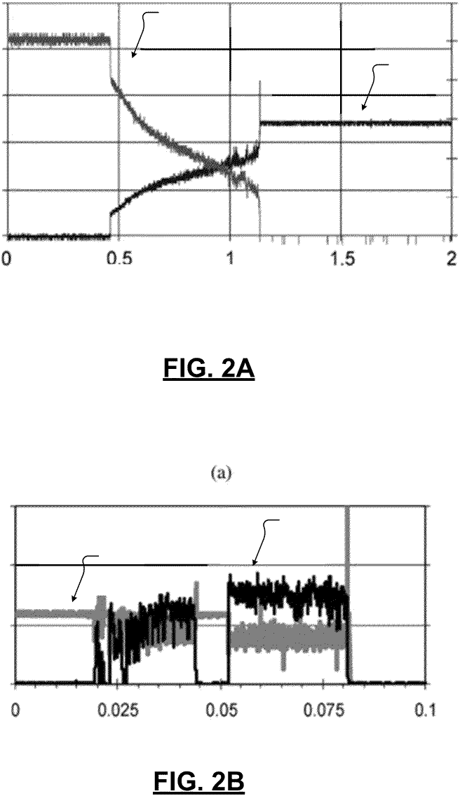

Referring now to FIGS. 2A and 2B, example current and voltage are shown as a function of time during a DC arc fault. DC arc faults include series or parallel arc faults. Both types of DC arc faults have unique current and/or voltage signatures that can be detected by processing the current waveforms measured using low-cost, high-bandwidth sensors. During charging, the current is typically higher and voltage is very low (close to zero). During a serial DC arc fault shown in FIG. 2A, there is a sudden drop in current to zero, a corresponding rise in voltage and then open circuit conditions. An example of a parallel DC arc fault is shown in FIG. 2B. As can be seen, the current and voltage have different characteristics as compared to the serial DC arc fault. In this example, the current falls a bit (to non-zero values) and voltage rises above zero.

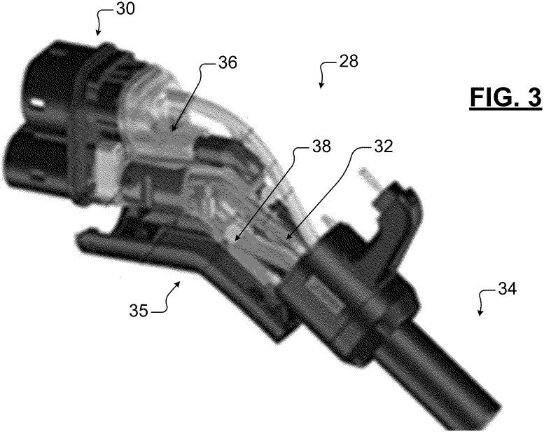

Referring now to FIG. 3, an example of a charger connector 28 is shown. A plug 30 is located at a vehicle-side end of the charger connector 28. A plurality of insulated wire conductors 32 extend from the plug 30 to a connection location for utility power. In some examples, a printed circuit board 36 is located adjacent to the plug 30 inside of a housing 35. In some examples, a current sensor 38 is arranged in the housing 35. In other examples, both current and voltage sensors are arranged in the housing 35.

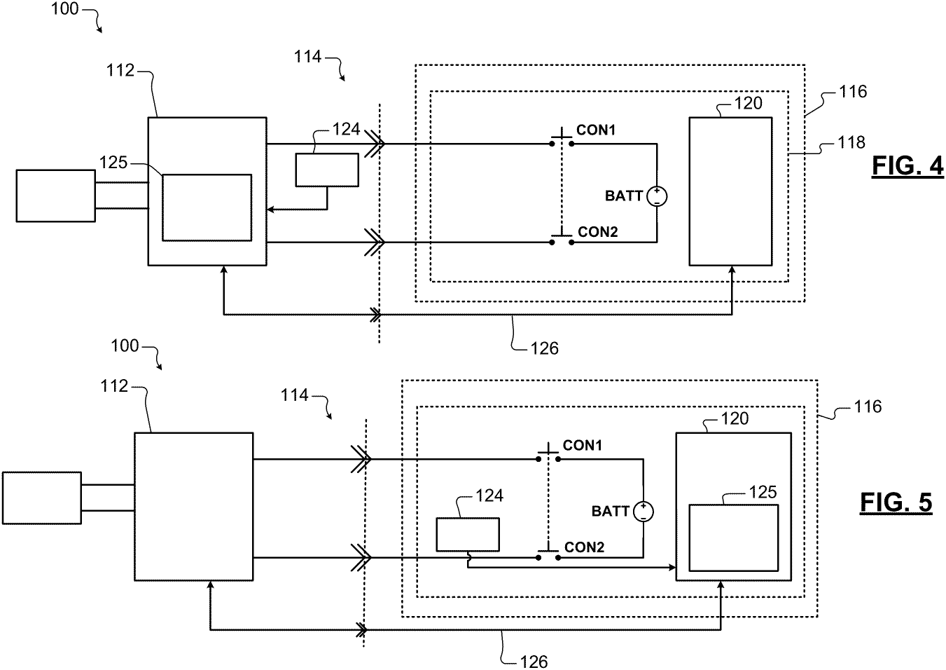

Referring now to FIGS. 4-7, examples of charging systems charging an electric vehicle are shown. In FIG. 4, a charging system 100 includes a charger-side controller 112, a charger connector 114 and a current sensor 124. In this example, the current sensor 124 is arranged on the charger side.

The electric vehicle 116 includes a battery system 118. The battery system 118 includes contactors CON1 and CON2 and a battery BATT including one or more battery cells, battery modules, and/or battery packs connected in series, parallel, and/or combinations thereof. The charger-side controller 112 communicates with the vehicle-side controller 120 via a conductor 126 such as a controller area network (CAN) bus.

With the current sensor 124 located on the charger side, an arc fault detection module 125 resides in the charger-side controller 112. The arc fault detection module 125 detects DC arc faults based on the measured current. When a DC arc fault is detected, the charger-side controller 112 reduces the charging current to zero within a predetermined period and sends a command to the vehicle side controller 120 to open the battery contactors when the charging current falls below a predetermined current threshold.

In FIG. 5, the current sensor 124 is located on the vehicle side. The vehicle-side controller 120 includes the arc fault detection module 125. When the DC arc fault is detected, the vehicle-side controller 120 sends a request to the charger-side controller 112 to ramp down the current to zero within a predetermined period. The vehicle-side controller 120 opens the battery contactors after the charging current falls below a predetermined threshold.

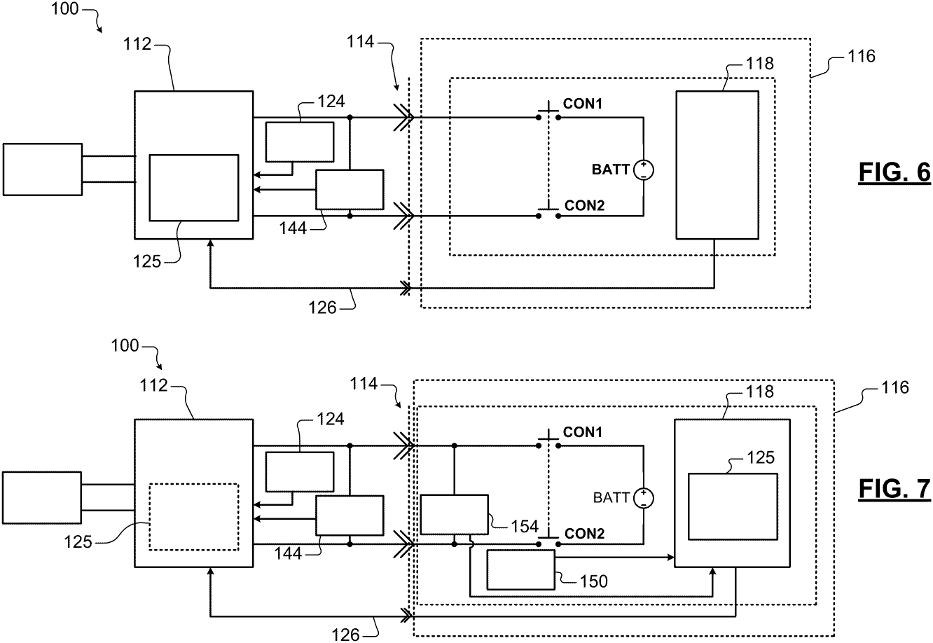

In FIG. 6, a voltage sensor 144 can be arranged on the charger side to sense voltage. Both voltage and current values are used by the arc fault detection module to diagnose DC arc faults.

In FIG. 7, a current sensor 150 and a voltage sensor 154 are also arranged on the vehicle side. With the current and voltage sensors located on both the vehicle side and charger sides, the arc fault detection module 125 compares both sets of currents and voltages. Either the charger-side controller 112 or the vehicle-side controller 120 can host the arc fault detection module 125. Alternately, both the charger-side controller 112 and the vehicle-side controller 120 host the arc fault detection module 125. When the DC arc fault is detected, the charger-side controller 112 ramps down current and the contactors CON1 and CON2 are opened after the charging current falls below a predetermined current threshold.

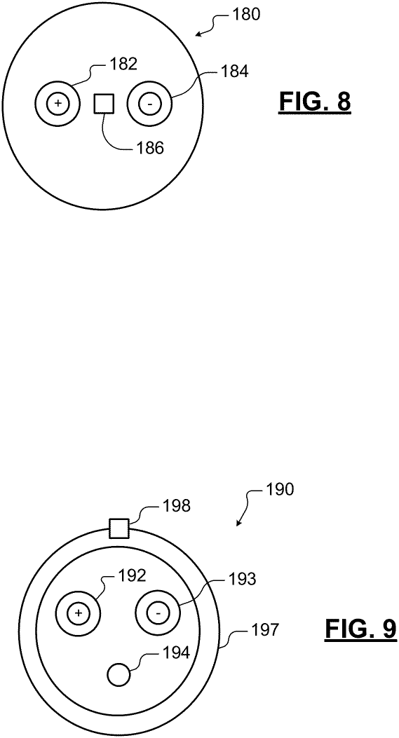

Referring now to FIG. 8, a charger plug or charger port 180 is shown to include a first connection 182 and a second connection 184. In some examples, the first connection 182 includes a male or female connector for a positive terminal and the second connection 184 includes a negative male or female connector. The first connection 182 and the second connection 184 of the charger plug or charger port 180 produce a naturally-enhanced field in locations there between. A current sensor 186 is arranged between the first connection 182 and the second connection 184.

In some examples, the current sensor 186 comprises a point field detector (PFD) such as an anisotropic magneto-resistive (AMR) sensor, a giant magneto-resistive (GMR) sensor, a tunnel magneto-resistive (TMR) sensor, a Hall effect sensor, or other suitable sensors. In some examples, the PFD sensor is a submillimeter high bandwidth PFD that is positioned in between the first connection 182 and the second connection 184 to detect the field and the current in the charge loop. Though a PFD sensor is shown, any low-cost, high-bandwidth field sensor can be used for sensing the current.

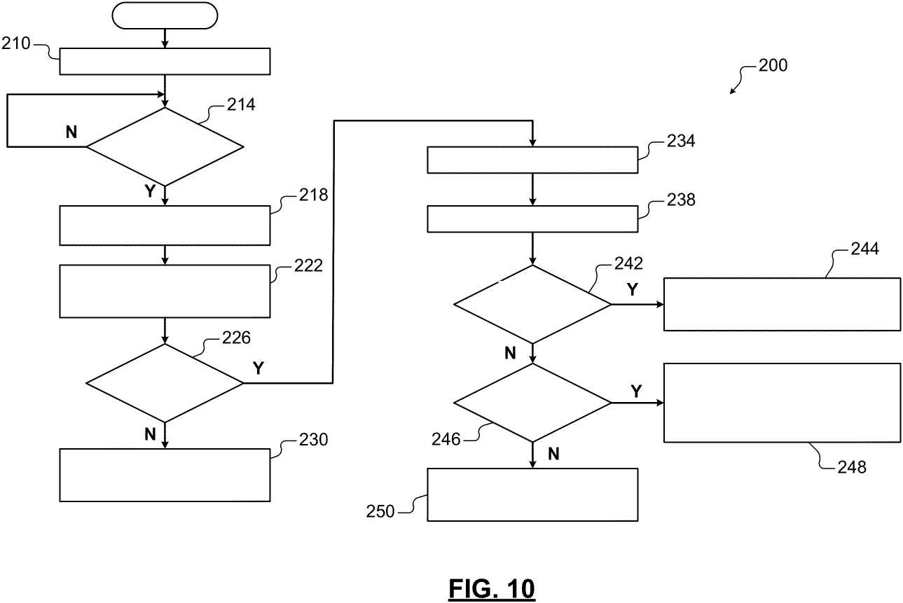

Referring now to FIG. 9, a plug 190 is shown to include a first connection 192, (e.g. a positive connection), a second connection 193 (e.g. a negative connection), and a third connection 194. A current sensor 198 is arranged around an outer insulation layer 197 of the plug 190.

In some examples, the current sensor 198 comprises a zero current core-based annular sensor arranged around the outer insulation layer 197 of the plug 190. The annular magnetic core around the positive and negative current experiences field cancellation from the regular charging currents. However, only the fault currents with unbalance fields will generate magnetic field inside the core. Due to this, the core can be very thin with low cross-sectional area. The current sensor 198 is very low cost and tightly integrated with the outer insulation layer 197 due to field nulling. With no loss of isolation or parallel fault issues, the low-field detector output will be close to zero. When a DC arc fault is detected, the charging system ramps down current and the vehicle-side controller opens the contactors after the current falls below a predetermined current threshold. While specific types of current sensors are shown and described, other types of current sensors can be used.

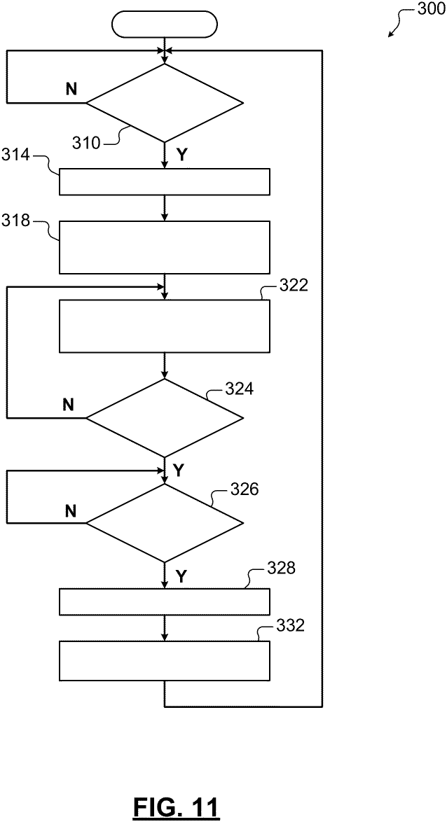

Referring now to FIG. 10, a method for operating the charging system is shown. At 210, a charging signal is sent. At 214, the method determines whether a start signal acknowledgement is received from the charger-side controller. At 218, key battery parameters are sent to the charger-side controller. At 222, the connected is locked and initial safety checks are performed. At 226, the method determines whether the safety checks are passed. If 226 is false, a diagnostic code is set and a message is sent to the user. If 226 is true, the method continues at 234 and the charger starts charging the battery. At 238, the vehicle-side controller is read. At 242, the method determines if there is a request to terminate charging. If 242 is true, then the charging current is ramped down to zero and the contactors are opened, the charging process is terminated, and the connector is unlocked.

If 242 is true, the method determines if an arc fault is detected. If 246 is true, the charging current is ramped down to zero and the contactors are opened, the charging process is terminated, and the connector is unlocked. A message is sent to the vehicle-side controller at 248. If 246 is false, the battery is charged in constant charge (CC) or constant voltage (CV) mode depending upon the charge request.

Referring now to FIG. 11, a method 300 for operating a charging system is shown. At 310, the method determines whether the start charging signal is received. At 314, the method recognizes the start of charging. At 318, the battery parameters and start permission signal are sent to the charger. At 322, the battery status and desired charging mode (CC or CV) are sent to the charger. At 324, the method determines whether a fault is indicated by the charger. If 324 is false, the method returns to 322. If 324 is true, the method continues with 326 and determines whether the charging current is less than a predetermined limit. If 326 is false, the method returns to 326. If 326 is true, the method opens the battery contactor at 328. At 332, the method sets a diagnostic code and sends a message to the user.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A charging system for an electric vehicle, comprising:
a charger connector configured to connect to a charge port on the electric vehicle and including:
a housing;
a first conductor passing through the housing;
a second conductor passing through the housing; and
a current sensor configured to sense current flowing through at least one of the first conductor and the second conductor to a battery system of the electric vehicle; and
a charger-side controller including an arc fault detection module configured to selectively identify a DC arc fault in response to measured current sensed by the current sensor and to stop charging the electric vehicle in response to detecting the DC arc fault.

2. The charging system of claim 1, wherein the current sensor has a bandwidth greater than 100 KHz.

3. The charging system of claim 1, wherein the current sensor comprises a point field detector (PFD).

4. The charging system of claim 3, wherein the current sensor is selected from a group consisting an anisotropic magneto-resistive (AMR) sensor, a giant magneto-resistive (GMR) sensor, a tunnel magneto-resistive (TMR) sensor, and a Hall effect sensor.

5. The charging system of claim 1, wherein when stopping charging, the charger-side controller is configured to:
decrease current output to the electric vehicle to zero; and
send a message to a vehicle-side controller to cause the vehicle-side controller to open a first contactor and a second contactor connecting the first conductor and the second conductor to the battery system after the measured current is less than a predetermined current threshold.

6. The charging system of claim 1, wherein the current sensor is arranged in the housing.

7. The charging system of claim 1, wherein the current sensor is arranged between the first conductor and the second conductor in the housing.

8. The charging system of claim 1, further comprising an insulation layer surrounding the first conductor and the second conductor, wherein the current sensor is arranged around the insulation layer.

9. The charging system of claim 1, further comprising a voltage sensor configured to sense voltage across the first conductor and the second conductor.

10. The charging system of claim 8, wherein:
the charger-side controller receives a second measured current and a second measured voltage from a vehicle-side controller, and
the arc fault detection module is configured detect the DC arc fault by comparing the measured current and the measured voltage to the second measured current and the second measured voltage, respectively.

11. A charging system for an electric vehicle, comprising:
a charge port on the electric vehicle configured to connect to a charger connector:
a first conductor configured to connect power from the charge port to a first terminal of a battery system;
a second conductor configured to connect power from the charge port to a second terminal of the battery system;
a current sensor configured to sense current flowing through at least one of the first conductor and the second conductor to the battery system; and
a vehicle-side controller including an arc fault detection module configured to selectively identify a DC arc fault in response to measured current output by the current sensor and to cause charging to stop in response to detecting the DC arc fault.

12. The charging system of claim 11, wherein the current sensor has a bandwidth greater than 100 KHz.

13. The charging system of claim 11, wherein the current sensor comprises a point field detector (PFD).

14. The charging system of claim 13, wherein the current sensor is selected from a group consisting an anisotropic magneto-resistive (AMR) sensor, a giant magneto-resistive (GMR) sensor, a tunnel magneto-resistive (TMR) sensor, and a Hall effect sensor.

15. The charging system of claim 11, further comprising:
a first contactor connecting the first conductor to the first terminal of the battery system; and
a second contactor connecting the second conductor to the second terminal of the battery system.

16. The charging system of claim 15, wherein when causing the charging to stop, the vehicle-side controller is configured to:
send a message to a charger-side controller to decrease current output to the electric vehicle to zero; and
open the first contactor and the second contactor after the measured current is less than a predetermined current threshold.

17. The charging system of claim 11, further comprising a voltage sensor configured to sense voltage across the first conductor and the second conductor.

18. The charging system of claim 11, wherein:
the vehicle-side controller receives a second measured current and a second measured voltage from a vehicle-side controller, and
the arc fault detection module is configured detect the DC arc fault by comparing the measured current and the measured voltage to the second measured current and the second measured voltage, respectively.
